(19) United States
(12) Patent Application Publication
(10) Pub. No.: US 2011/0266681 A1
(43) Pub. Date: Nov. 3, 2011

(54) ELECTRONIC COMPONENT AS WELL AS METHOD FOR ITS PRODUCTION

(76) Inventors: Richard Fix, Gerlingen (DE); Denis Kunz, Untergruppenbach (DE); Andreas Krauss, Tuebingen (DE); Alexander Martin, Regensburg (DE)

(21) Appl. No.: 12/998,062

(22) PCT Filed: Jul. 15, 2009
(86) PCT No.: PCT/EP2009/059010

§ 371 Date: Jun. 22, 2011

(30) Foreign Application Priority Data
Sep. 15, 2008 (DE) 10 2008 042 107.3

(51) Int. Cl. H01L 23/48; H01L 21/28

(52) U.S. Cl. 257/763; 438/656; 257/E23.01; 257/E21.158

(57) ABSTRACT

An electronic component includes at least one patterned layer of an electrically conductive material on a substrate, a protective layer of a second material being deposited on the patterned layer of the electrically conductive material. The second material is baser than the electrically conductive material of the patterned layer. In a method for producing the electronic component, the patterned layer of the electrically conductive material is deposited on the substrate in a first step, and the protective layer of the second material, which is baser than the electrically conductive material of the patterned layer, is deposited on the patterned layer in a second step.

### BACKGROUND OF THE INVENTION

1. Field of the Invention

The present invention relates to an electronic component and a method for producing an electronic component having a patterned layer.

2. Description of Related Art

In electronic components, a patterned layer of an electrically conductive material is generally applied on a substrate. The patterned layer is frequently used as circuit tracks or a circuit track system, by which a variety of functions is able to be realized or by which a plurality of functional elements is connected to each other on the patterned layer. Especially in the case of electronic components used in a high temperature range, the patterned layers are generally made of aluminum, gold and/or platinum. This avoids oxidation of the patterned layer.

In a substrate made from a semiconductor material, such as gallium nitride or silicon carbide, for instance, titanium, tantalum silicide, nickel-chromium alloys or also other suitable materials, especially their corresponding oxides, are frequently used as bonding agent in order to improve the adhesion of the patterned layer made of the noble metal, on the semiconductor material.

However, at a high temperature in an oxidizing atmosphere, e.g., in the presence of air, oxidation of the baser materials employed as bonding agent frequently occurs, so that the patterned layer and thus the circuit tracks and metallic supply lines that are represented by the patterned layer, may lose their electrical function.

To protect against corrosion, it is known, for example, to deposit a protective layer or a passivation of a dielectric material on the electronic component. However, it is often impossible to produce these protective layers in gastight manner. Specifically under high-temperature stressing, different coefficients of thermal expansion between different protective layer materials and the metal of the patterned layer or the material of the substrate result in thermo-stressing, which can cause tears and defects. As a result, oxygen may reach the supply lead or the patterned layer, especially at high temperatures, and oxidize the base materials into the corresponding oxide compounds according to the electrochemical potential.

From published German patent application document DE-A 10 2005 034 667, for example, the production of a semiconductor element is known. There, a masking layer is applied on a patterned magnetic stack. The masking layer preferably has a dielectric material. Once the masking material has been applied, an etching step may be carried out. Then the deposition of another insulating layer is described. However, the described protective layers of dielectric material are unable to protect the semiconductor component from undesired oxidation during subsequent production steps. Also, the long-term stability of semiconductor components in a corrosive environment and in an operation at high temperatures is not increased.

### BRIEF SUMMARY OF THE INVENTION

An electronic component designed according to the present invention includes at least one patterned layer of an electrically conductive material applied on a substrate. An additional layer of a second material is applied on top of the layer of an electrically conductive material, the second material being baser than the electrically conductive material of the patterned layer.

The second, baser material, which is applied on top of the electrically conductive material of the patterned layer, acts as sacrificial anode, and reacts to form a corresponding oxide in the presence of oxygen. This oxide forms an active protective layer and passivates the materials or the composite material lying underneath, thereby protecting it from further oxygen penetration. Oxidation-susceptible bonding agents, in particular, which are used to improve the adhesion of the patterned layer on the substrate, are able to be protected in this manner. But even when dispensing with a bonding agent, the patterned layer is able to be protected from oxidation. In this case, for example, it is also possible to produce the patterned layer from a baser material. The even baser material of the applied protective layer oxidizes and thus forms a protective layer for the semiconductor material. The developed oxide layer is generally gastight and prevents further penetration of oxygen to the patterned layer disposed underneath. In general, the oxidation of the second material goes hand in hand with an increase in volume and mass, which causes an increase in the passivation effect due to the thicker oxide layer. This leads to slowing of the oxidation or even to a standstill. The electronic components produced in this manner may be used even at high temperatures and have an oxidation-stable patterned layer at these temperatures. A high temperature within the meaning of the present invention is a temperature above 300° C.

The electrically conductive material for the patterned layer is preferably selected from the group made up of aluminum, gold, platinum, rhodium as well as alloys of these metals. In particular when the electronic component is used in the high-temperature range, gold or platinum is employed as electrically conductive material for the patterned layer. The use of gold or platinum prevents the patterned layer from oxidizing under the influence of oxygen and from thereby losing its electrical function. The advantage of using aluminum is its better electrical conductivity in comparison with gold or platinum. However, aluminum usually produces an oxide layer at the surface, which may lower the electrical conductivity and make suitable contacting of the component more difficult or even impossible.

The material for the protective layer, which is baser than the electrically conductive material of the patterned layer, is preferably selected from the group made up of magnesium, zinc, aluminum, titanium and mixtures thereof as well as their alloys. In general, the protective layer of the metal is first deposited on the patterned layer. During operation of the component, the metal of the protective layer usually oxidizes to its oxide. As an alternative, however, it is also possible to already selectively oxidize the metal following the application. In general, the oxidation of the metal leads to an increase in volume and mass, which causes the passivating effect to increase as the oxide layer becomes thicker.

If aluminum, for example, is selected as electrically conductive material for the patterned layer, then a material that is baser than aluminum is usually selected for the protective layer.

A bonding agent is preferably used to improve the adhesion of the patterned layer of the electrically conductive material on the substrate, which bonding agent is included between the patterned layer of the electrically conductive material and the substrate. For instance, titanium, titanium nitride, tantalum silicide, nickel-chromium alloys or other materials known to the expert, which improve the adhesion of the electrically conductive material of the patterned layer on the substrate, are used as bonding agent. The material of the bonding agent is generally baser than the material of the patterned layer. As a result, the bonding agent tends to oxidize in the presence of oxygen. As a rule, however, an oxidation of the bonding agent causes it to become electrically insulating. Especially in the case of electronic components for which an electrical connection is desired between the patterned layer of the electrically conductive material and the substrate, this leads to undesired effects. The protective layer of the second material, which is baser than the electrically conductive material of the patterned layer, prevents the bonding agent from oxidizing. This makes it possible to prevent the loss of the electrical function of the component due to an oxidation of the bonding agent.

The substrate on which the patterned layer is deposited preferably is a semiconductor material. Suitable semiconductor materials are gallium nitride or silicon carbide, for instance. In particular, electronic components whose substrate is a semiconductor material are also microelectronic components. These are semiconductor chips, for example. Such electronic components are, for instance, high-temperature field-effect transistors as they are used as gas sensors, among other things.

The patterned layer of the electrically conductive material generally has a layer thickness in the range of 0.1 to 5 μm. Such a layer thickness is usually sufficient to ensure the function of the electronic component. Moreover, it allows the corresponding components to be positioned in a small space.

The protective layer of the second material preferably has a layer thickness in a range between 10 nm to 100 μm. The layer thickness of the protective layer preferably lies within a range from 100 nm to 10 μm. Such a layer thickness already suffices to achieve a passivation of the patterned layer and possibly the bonding agent in order to ensure the function of the electronic component.

If the semiconductor material of the substrate may possibly be damaged when using the electronic component in a corrosive environment, in particular at high temperatures, it is preferred if a passivation layer is deposited on the semiconductor material. However, in the methods known from the related art, it is obvious that the deposited passivation layers adhere only poorly, in particular on circuit tracks containing aluminum, gold and/or platinum. Especially at the edges between semiconductor substrate, circuit track and vapor phase, the passivation layers may tear due to poor adhesion, so that large regions of the electronic component are exposed to the surrounding gas atmosphere without protection. This disadvantage is able to be remedied by the protective layer of the second material according to the present invention, which is baser than the electrically conductive material of the patterned layer. For the passivation, the surface of the electronic component is covered by a passivation layer following the deposition of the protective layer. The protective layer of the baser material simultaneously acts as bonding agent for the passivation layer. This prevents tearing of the passivation layer, especially in the region of the patterned layer of the electrically conductive material.

The method for producing an electronic component according to the present invention encompasses the following steps:

(a) Depositing a first layer of an electrically conductive material on a substrate;

(b) Depositing a second layer of a second material, which is baser than the electrically conductive material of the first layer, on the first layer.

The deposition of the first layer in step (a) may be carried out using various methods known to one skilled in the art. For example, it is possible to deposit the patterned layer on the substrate by sputtering or vapor deposition. As an alternative, however, the first layer of the electrically conductive material may also be applied on the substrate using an electrochemical process, such as a currentless or galvanic deposition, for example. To produce a patterned layer, for instance, it is possible to first apply a photoresist, which is exposed according to the pattern to be produced. The unexposed regions are normally removed. In a next step, a bonding agent may possibly applied. The electrically conductive material for the patterned layer is deposited on top of the bonding agent. Subsequently, the protective layer of the second material, which is baser than the electrically conductive material of the first layer, is applied. Finally, the regions in which the material for the bonding agent, the patterned layer and the protective layer had been deposited on the photoresist are removed together with the photoresist. What remains is a patterned layer on the substrate in which the bonding agent is contained between the patterned layer and the substrate, and the protective layer on top of the patterned layer.

The deposition of the protective layer may likewise be carried out by vapor deposition, sputtering or by electrochemical deposition, for instance.

Alternatively, it is also possible, however, to pattern the first layer even prior to depositing the protective layer in step (b). When using a photoresist, for example, and once the first layer of the electrically conductive material has been deposited, this may be done by removing the regions that are not part of the desired pattern of the patterned layer, i.e., when a photoresist is employed, the regions in which the material of the first layer was deposited on the photoresist, for example. In addition to the use of a photoresist for patterning, however, any other method known to one skilled in the art is suitable for depositing a patterned layer on the substrate.

Once the protective layer has been applied, it is preferred if the material of the protective layer is oxidized in a further step. The oxidation of the material produces a gastight layer, which prevents oxygen from reaching the bonding agent or the first layer of the electrically conductive material. The oxidation of the protective layer is achieved by heating the electronic component in an oxidizing atmosphere, for example. Air is preferably used as oxidizing atmosphere. The temperature to which the electronic component is heated generally lies in a range between 100 and 600° C. The upper temperature limit is defined by the materials used for the substrate, the bonding agent, and the patterned layer. The temperature to which the electronic component is heated for oxidation purposes preferably lies below the melting temperatures or the decomposition temperatures of the corresponding materials, in order to prevent damage to the electronic component.

If a passivation layer is deposited on the electronic component, then the passivation layer is deposited on the surface of the entire electronic component following the deposition of the protective layer on the patterned layer in step (b). The deposition of the passivation layer is achieved by CVD (chemical vapor deposition) methods, for instance LPCVD (low pressure CVD), PECVD (plasma-enhanced CVD), ALD (atomic layer deposition), thermal oxidation, plasma methods or sputtering and vapor deposition methods.

In one preferred specific development, prior to depositing the passivation layer, the protective layer is first heated under a protective gas atmosphere to a temperature in the range between 50° C. to 650° C., in particular in the range from 250° C. to 450° C. Then, in the presence of air, the electronic component is heated to a temperature in the range from 50° C. to 650° C., especially in the range from 250° C. to 450° C.

This further enhances the effect of the protective layer as a bonding agent layer for the passivation layer.

The protective gas that is used as atmosphere is argon or nitrogen, for example, or a mixture of argon and nitrogen.

### BRIEF DESCRIPTION OF THE DRAWINGS

FIGS. 1.1 through 1.4 show four steps of a method for producing a component according to the present invention.

FIGS. 2.1 and 2.2 show two steps of an alternative method for producing a component according to the present invention

FIG. 3 shows a component according to the present invention, including a passivation layer.

### DETAILED DESCRIPTION OF THE INVENTION

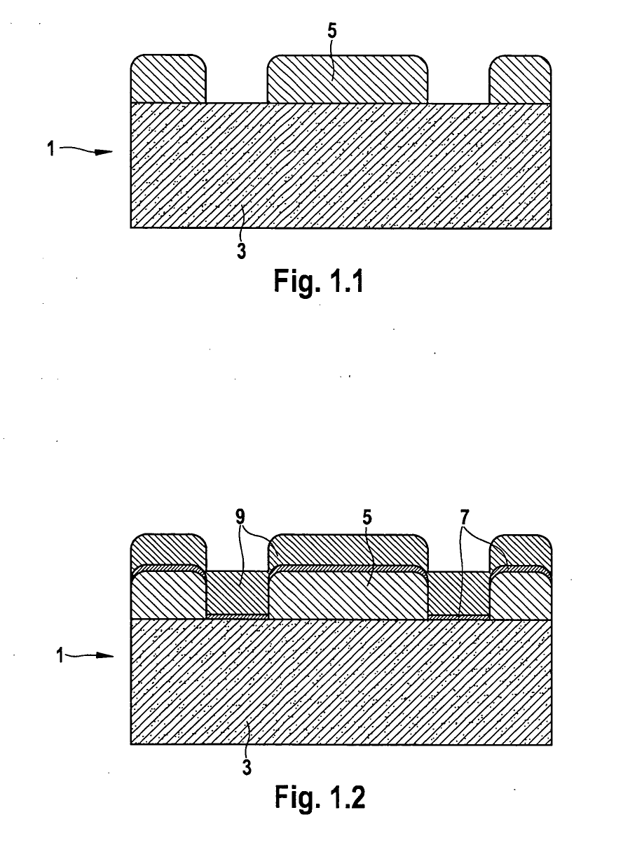

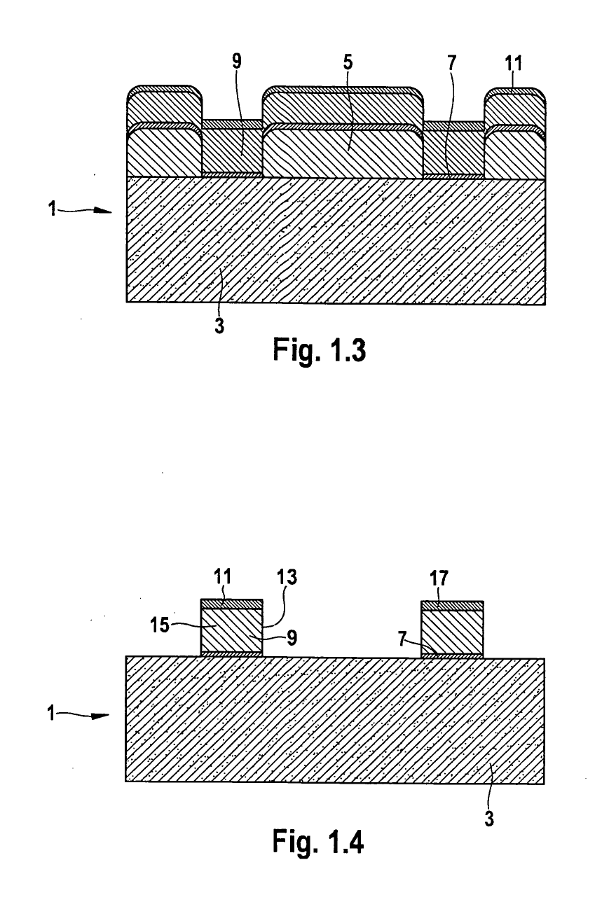

FIG. 1.1 shows a first step of a method according to the present invention for producing an electronic component.

For the production of an electronic component 1, a photoresist 5 is applied on a substrate 3. A negative exposure of photoresist 5 takes place subsequently, so that the regions that are going to form a patterned layer of an electrically conductive material are not exposed and the regions that are to remain uncoated are exposed. Unexposed photoresist 5 is subsequently removed. This produces a patterned negative layer of the patterned layer to be created.

After removal of the unexposed photoresist, a bonding agent 7 is initially applied across the full surface of substrate 3 having the applied photoresist 5. Any method known to one skilled in the art may be used for the application of bonding agent 7. For example, bonding agent 7 may be applied by vapor deposition or sputtering, or else also by other thin-film technologies known to one skilled in the art. As previously described already, titanium, tantalum silicide or nickel-chromium alloys, for example, are suitable bonding agents. In a further step, an electrically conductive material is applied, once again across the entire surface of substrate 3. The electrically conductive material adheres to bonding agent 7. Electronic component 1 having bonding agent 7 applied across the entire surface and having conductive material 9 on substrate 3 is shown in FIG. 1.2.

If conductive material 9 adheres well to substrate 3, it is possible to omit bonding agent 7.

In a further step, which is illustrated in FIG. 1.3, a baser material 11 is applied on conductive material 9 in order to form a protective layer. The application of baser material 11 likewise takes place across the entire surface, e.g., using suitable thin-film technologies such as vapor deposition or sputtering, or electrochemical deposition.

The layer thickness of conductive material 9 deposited on the substrate preferably lies within a range from 0.1 to 5 μm. Preferably, the layer of baser material 11 deposited thereon lies in a range between 10 nm to 100 μm, preferably within a range of 100 nm through 10 μm. The deposition of baser material 11 transforms the conductive material of the patterned layer into a cathode, and baser material 11 into an anode. In the process, the cathode of conductive material 9 and the anode of baser material 11 form a corrosion element. When attacked by oxygen, baser material 11 forming the anode is sacrificed by oxidation. As described above, magnesium, zinc, aluminum, titanium or mixtures of these metals, for example, are suitable as baser material 11.

In a deposition process based on thin-film technology, the deposition of conductive material 9 and baser material 11 may take place in the same process step. This avoids additional process costs.

Once baser material 11 has been deposited on conductive material 9, the regions of the layers in which photoresist 5 is situated on the substrate are removed. What remains is a conductive structure in which bonding agent 7 is applied directly on substrate 3 and on which bonding agent 7, conductive material 9 and baser material 11 form a layer composite. The removal of photoresist 5 having bonding agent 7, conductive material 9 and baser material 11 lying on top is accomplished with the aid of a lift-off process known to one skilled in the art. For example, the photoresist may be removed with the aid of a suitable solvent, thereby also removing the material lying on top of photoresist 5.

However, in a patterned layer produced according to this method, sides 13 of patterned layer 15 are unprotected. A protective layer 17 made of baser material 11 is situated only on the top surface of patterned layer 15. Nevertheless, a protective layer 17 that is disposed only on the top surface of patterned layer 15 may already suffice depending on a passivation possibly performed retroactively, or as a function of the use of electronic component 1.

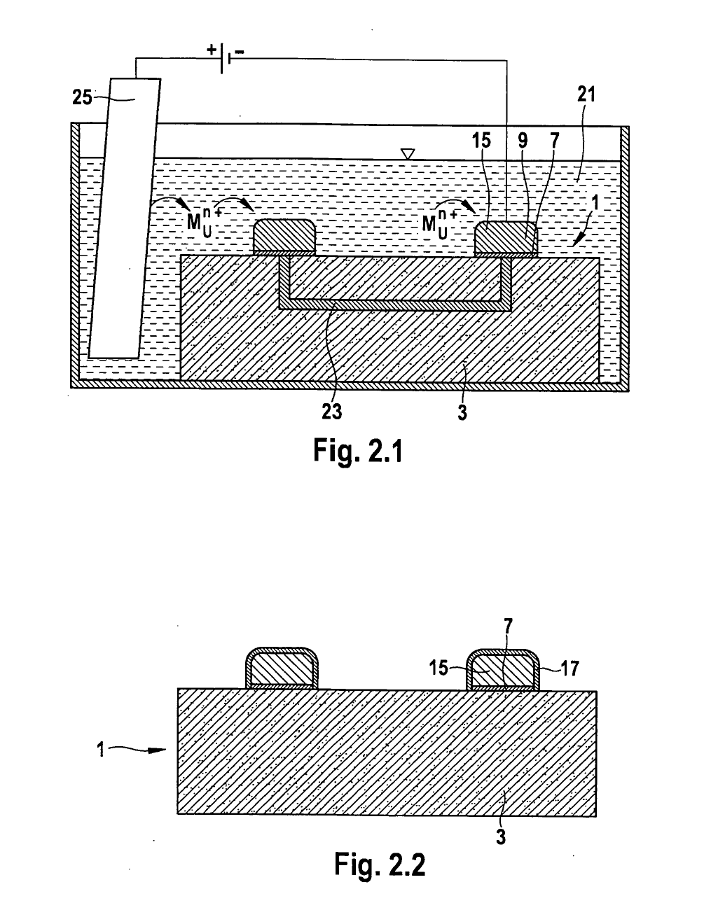

An alternative method for depositing protective layer 17 is shown in FIG. 2.1.

For this purpose, patterned layer 15 of conductive material 9 is first deposited on substrate 3. Various methods known to one skilled in the art may be used for depositing patterned layer 15. For example, a lift-off method may be used for depositing patterned layer 15 as well; in this case, a negative structure having a photoresist is initially deposited on substrate 3 and conductive material 9 is deposited on top of it. Once conductive material 9 has been deposited, the photoresist together with the conductive material lying on top of the photoresist is removed from substrate 3, so that patterned layer 15 is left on substrate 3. However, any other method known to the expert for producing patterned layer 15 may be used. Here, too, the adhesion of patterned layer 15 on substrate 3 may be improved by applying a bonding agent 7 between patterned layer 15 and substrate 3.

Once patterned layer has been produced, protective layer 17 is deposited. Protective layer 17 is deposited with the aid of an electrochemical method as illustrated in FIG. 2.1, for example. This may be both a currentless and a galvanic deposition. Shown here in schematized manner is a galvanic deposition for protective layer 17.

To deposit protective layer 17 on top of patterned layer 15, electronic component is positioned in an electrolyte bath 21. Electrolyte bath 21 usually contains a solution of a salt of the metal that is to be deposited on patterned layer 15 as protective layer 17. In order to deposit protective layer 17 on patterned layer 15, patterned layer 15 is switched cathodically. Parts of patterned layer 15 that are not connected to each other are interconnected, preferably via auxiliary contacts 23. Auxiliary contacts 23 may likewise be implemented in the form of patterned layer 15, for instance, but any other contacts with whose aid individual regions of patterned layer 15 are able to be connected are conceivable as well. For example, the individual regions of patterned layer 15 may also be interconnected with the aid of wires or other contacting elements. In order to enable a deposition of protective layer 17 on patterned layer 15, an anode 25 is additionally included in electrolyte bath 21. Anode 25 may be made of a non-dissolving material, or alternatively, it may be implemented as sacrificial anode. If anode 25 is implemented as sacrificial anode, then it preferably includes the material that is deposited on patterned layer 15 as protective layer 17. In the process, metal ions from anode 25 dissolve in electrolyte bath 21 and then are deposited on patterned layer 15.

The metallic salt may be dissolved, for instance, in a hydrous medium or in an organic and/or ionic liquid. In general, however, the metallic salt is dissolved in a hydrous medium.

To deposit a protective layer 17 on patterned layer 15, for example, an aluminum salt, such as an anhydrous aluminum chloride, for instance, may be dissolved in an organic solvent or an ionic fluid. Suitable as organic solvents are, for example, diethyl ether or tuluol. A suitable ionic fluid is ethylene pyridinium chloride, for instance. The galvanic deposition takes place under a protective gas atmosphere using a direct current of approximately 0.5 to 2.5 A/dm^{2.}. In the process, an aluminum layer is deposited on patterned layer 15 as protective layer 17.

To ensure that the deposition takes place only on patterned layer 15, protective layer 17 is also deposited along the sides of patterned layer 15 in the method variant shown in FIG. 2.1. This is illustrated in FIG. 2.2.

Because protective layer 17 is also deposited along the sides of patterned layer 15, bonding agent 7 is enclosed by protective layer 17 as well, thereby making it impossible for oxygen to reach bonding agent 7. An improvement in the protection is achieved by the oxidation of the material of protective layer 17. In this context it is possible, for one, that the oxidation takes place during operation of the electronic component, but for another, it is also possible to oxidize baser material 11 of protective layer 17 in a selective manner. In this case, the material of protective layer 17 is brought into a condition in which no further oxidation takes place. For example, the selective oxidation of the material of protective layer 17 is implemented by heating the electronic component in an oxidizing atmosphere to a temperature in the range between 100 and 600° C. For example, any oxygen-containing gas, especially air, is suitable as oxidizing atmosphere. The oxide layer produced in this manner enhances the passivation effect of protective layer 17. This is due to the fact that the layer thickness of protective layer 17 increases because of the oxidation. This makes it possible to slow the oxidation of bonding agent 7 and patterned layer 15 considerably, or the oxidation comes to a complete standstill.

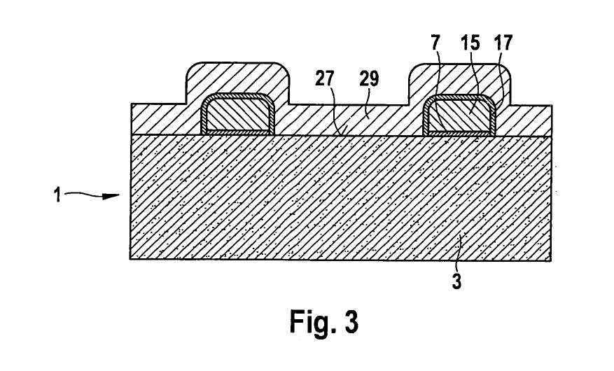

FIG. 3 shows an electronic component having a passivation layer.

When an electronic component 1, especially one having a substrate 3 made of a semiconductor material, is used in a corrosive environment, a passivation layer 29 is preferably deposited on surface 27 of electronic component 1. Passivation layer 29 also covers patterned layer 15. Improved adhesion of passivation layer 29 in the region of patterned layer 15 made of conductive material 9, in particular, is achieved by depositing protective layer 17 made of baser material 11. If a passivation layer 29 is deposited, then it is usually not necessary to oxidize protective layer 17 first. However, improved adhesion of passivation layer 29 may be achieved if, following the deposition, protective layer 17 is first heated to a temperature in the range from 50° C. to 650° C. under a protective gas atmosphere, and subsequently, in the presence of air, to a temperature in the range from 50° C. to 650° C.

Argon, nitrogen or a mixture of argon and nitrogen are preferably used as protective gas.

Also in instances where protective layer 17 serves as bonding agent layer for passivation layer 29, in particular, the baser material from which protective layer 17 is formed is preferably selected from the group consisting of magnesium, zinc, aluminum, titanium and mixtures thereof.

1-15. (canceled)

16. An electronic component, comprising:
a substrate;
at least one patterned layer made of an electrically conductive material and situated on the substrate; and
a protective layer made of a second material and deposited on top of the patterned layer made of the electrically conductive material, wherein the second material is baser than the electrically conductive material of the patterned layer.

17. The electronic component as recited in claim 16, wherein the electrically conductive material is selected from the group made up of aluminum, gold, and platinum.

18. The electronic component as recited in claim 17, wherein the second material which is baser than the electrically conductive material of the patterned layer includes at least one of magnesium, zinc, aluminum and titanium.

19. The electronic component as recited in claim 18, further comprising:
a bonding agent included between the patterned layer of the electrically conductive material and the substrate.

20. The electronic component as recited in claim 18, wherein the substrate contains a semiconductor material.

21. The electronic component as recited in claim 18, wherein the patterned layer of the electrically conductive material has a layer thickness in the range between 0.1 to 5 μm.

22. The electronic component as recited in claim 21, wherein the protective layer of the second material has a layer thickness in the range from 10 nm to 100 μm.

23. The electronic component as recited in claim 21, wherein the surface of the electronic component is covered by a passivation layer.

24. A method for producing an electronic component, comprising:
(a) depositing a patterned layer of an electrically conductive material on a substrate; and
(b) depositing a protective layer of a second material on the patterned layer, wherein the protective layer is baser than the electrically conductive material of the patterned layer.

25. The method as recited in claim 24, wherein the protective layer is applied by one of vapor deposition, sputtering, or electrochemical deposition on the patterned layer.

26. The method as recited in claim 25, wherein the second material of the protective layer is oxidized following the deposition in step (b).

27. The method as recited in claim 26, wherein the oxidizing of the second material of the protective layer is achieved by heating in an oxidizing atmosphere to a temperature in the range from 100 to 600° C.

28. The method as recited in claim 25, further comprising:
depositing a passivation layer on the surface of the entire electronic component after the protective layer has been deposited on the patterned layer in step (b).

29. The method as recited in claim 28, further comprising:
prior to depositing the passivation layer, heating the electronic component under a protective gas atmosphere to a temperature in the range from 50° C. to 650° C., and then heating the electronic component to a temperature in the range from 50° C. to 650° C. in the presence of air.

30. The method as recited in claim 29, wherein the protective gas includes at least one of argon and nitrogen.
